(19) United States
(12) Patent Application Publication
(10) Pub. No.: US 2008/0053689 A1
(43) Pub. Date: Mar. 6, 2008

(54) Substrate for high-speed circuit

(75) Inventors: Tzong-Lin Wu, Taipei City (TW); Sin-Ting Chen, Gangshan Township (TW); Ting-Kuang Wang, Tainan City (TW)

Correspondence Address: BIRCH STEWART KOLASCH & BIRCH, PO BOX 747, FALLS CHURCH, VA, 22040-0747, US

(73) Assignee: National Taiwan University

(21) Appl. No.: 11/594,864

(22) Filed: Nov. 9, 2006

(30) Foreign Application Priority Data
Sep. 1, 2006 (TW) 095132480

(51) Int. Cl. H05K 1/16

(52) U.S. Cl. 174/260; 361/760

(57) ABSTRACT

A substrate for circuits is provided in this invention. The substrate includes a first voltage reference plane, a second voltage reference plane, a first dielectric layer, and a plurality of second dielectric materials embedded in the first dielectric layer. The first dielectric layer is between the first and second voltage reference planes. Each of the plurality of second dielectric materials includes a first end contacted with the first voltage reference plane and a second end contacted with the second voltage reference plane. The dielectric constant of the first dielectric layer is different from the dielectric constant of the second dielectric materials.

### BACKGROUND OF THE INVENTION

1. Field of the Invention

The present invention relates to a substrate for circuits and, more particularly, to a substrate for high-speed circuits.

2. Description of the Prior Art

With the trend of high operation frequencies in digital circuits, many parasitic effects induced by passive structures have been getting worse. Parasitic capacitors and parasitic inductors cause the signal quality to deteriorate, and they also cause electromagnetic interference (EMI) problems.

Taking a printed circuit board (PCB) as an example, when the voltage statuses of circuits on the PCB are rapidly switched, parasitic components generate transient voltages between power supply planes of the PCB. These transient voltages are called ground bounce noises (GBN) or simultaneously switching noises (SSN). The noises may induce errors in logic judgments of circuits. In PCBs, the power supply planes can be viewed as parallel waveguide structures. The GBNs between the power supply planes make the power supply planes resonate and accordingly result in EMIs. Signal quality is severely affected by GBNs especially near resonant frequencies. To prevent EMIs, how to eliminate GBNs becomes an important issue for PCB of high-speed circuits and packaging techniques thereof.

One method for eliminating GBNs in prior arts is adding decoupling capacitors near noise sources, so as to provide grounding paths for noises. However, because capacitors have parasitic inductances in themselves, their performance in eliminating GBNs is not so good.

Another method for eliminating GBNs is cutting rectangular crevices on power supply planes. If the crevices are complete and closed, their performance in eliminating GBNs is good. Nevertheless, to make the power supply planes inside and outside the crevices have an equal voltage potential, there must be a passage between the power supply planes inside and outside the crevices. For this reason, the performance in eliminating GBNs is significantly reduced.

Besides, electromagnetic band-gap (EBG) structures can also be used to eliminate GBNs. Designing EBG structures on metal layers of power supply planes can replace decoupling capacitors to provide broadband noise suppression, thus also reducing the cost of production. However, power supply planes are also return paths for currents from signal layers. EBG structures on metal layers of power supply planes destroy the completeness of return paths and therefore worsen the quality of signal transmission.

### SUMMARY OF THE INVENTION

To solve the aforementioned problems, this invention provides a new EBG structure located within the dielectric layer between two power supply planes. In this invention, the metal layers of the power supply planes are not destroyed. Therefore, the substrate, according to this invention, provides good return paths for currents from signal layers and improves the quality of signal transmission. Besides, the EBG structure, according to this invention, provides broadband noise suppression without using additional decoupling capacitors. Hence, costs of manufacturing the substrates can be reduced.

One preferred embodiment, according to this invention, is a substrate for circuits. The substrate includes a first voltage reference plane, a second voltage reference plane, a first dielectric layer, and a plurality of second dielectric materials embedded in the first dielectric layer. The first dielectric layer is located between the first voltage reference plane and the second voltage reference plane. Each of the plurality of second dielectric materials includes a first end contacted with the first voltage reference plane and a second end contacted with the second voltage reference plane. The dielectric constant of the first dielectric layer is different from the dielectric constant of the second dielectric materials.

The objective of the present invention will no doubt become obvious to those of ordinary skill in the art after reading the following detailed description of the preferred embodiment, which is illustrated in the various figures and drawings.

### BRIEF DESCRIPTION OF THE APPENDED DRAWINGS

FIG. 1 illustrates the substrate for circuits in one preferred embodiment according to this invention.

FIG. 2 shows the simulated and measured results for the substrate for circuits according to this invention.

FIG. 3(A) and FIG. 3(B) are perspective drawings of the first dielectric layer.

FIG. 4 shows the second dielectric materials in the shape of irregular pillar.

FIG. 5 illustrates a multi-layer PCB according to this invention.

FIG. 6(A) shows the simulated eye diagram for the substrate according to this invention. FIG. 6(B) shows the simulated eye diagram for a substrate without the second dielectric materials.

### DETAILED DESCRIPTION OF THE INVENTION

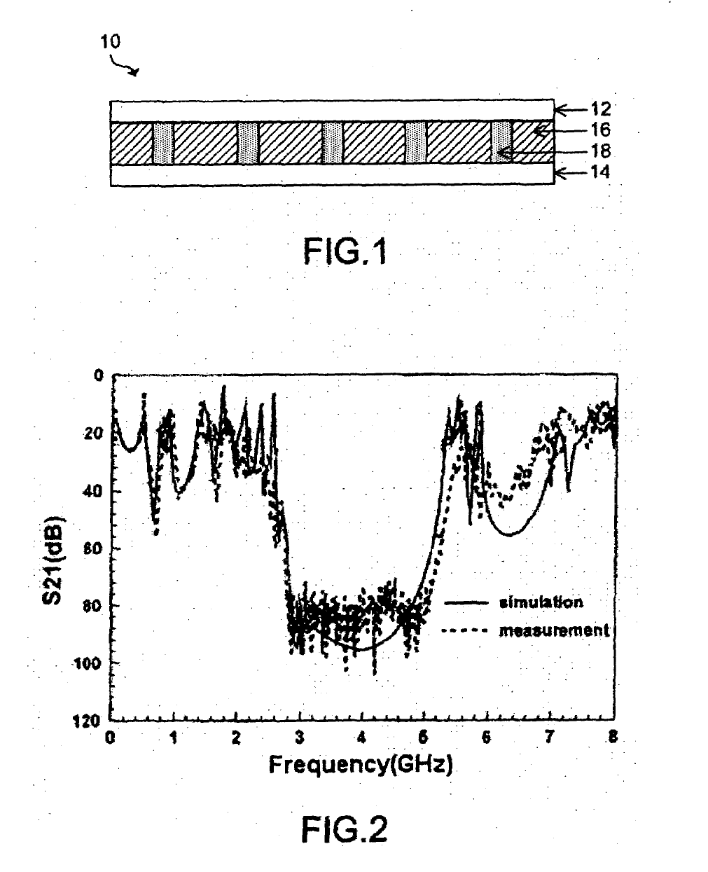

One preferred embodiment, according to this invention, is a substrate for circuits. Please refer to FIG. 1, which illustrates the substrate 10. The substrate 10 includes a first voltage reference plane 12, a second voltage reference plane 14, a first dielectric layer 16, and a plurality of second dielectric materials 18 embedded in the first dielectric layer 16. The first voltage reference plane 12 and the second voltage reference plane 14 can be a power plane and a ground plane, respectively.

In actual applications, each of the plurality of the second dielectric materials 18 can be ceramic material; the first voltage reference plane 12 and the second voltage reference plane 14 are generally metal planes.

As shown in FIG. 1, the first voltage reference plane 12 is parallel to or substantially parallel to the second voltage reference plane 14; the first dielectric layer 16 is located between the first voltage reference plane 12 and the second voltage reference plane 14. Each of the plurality of second dielectric materials 18 includes a first end contacted with the first voltage reference plane 12 and a second end contacted with the second voltage reference plane 14. In actual application, the ends of the second dielectric materials 18 may be plated with conductive metal, such as silver.

According to this invention, the dielectric constant of the first dielectric layer 16 is different from the dielectric constant of the second dielectric materials 18. In this embodiment, the dielectric constant of the second dielectric materials 18 is higher than that of the first dielectric layer 16. Generally, the dielectric constant of the first dielectric layer 16 is approximately 2. In one embodiment according to this invention, the dielectric constant of the second dielectric materials 18 is equal to 102, and the radius of each of the second dielectric materials 18 equals 2 mm.

Because of the difference between the dielectric constants, the first dielectric layer 16 and the second dielectric materials 18 form a broadband stop band for electromagnetic waves. In this stop band, noises cannot propagate easily. Through appropriate design of dielectric constants of the first dielectric layer 16 and the second dielectric materials 18, the frequency range and bandwidth of the stop band can be determined, and noises can accordingly be suppressed. The theories relative to this invention are mentioned in “A Photonic Crystal Power/Ground Layer for Eliminating Simultaneously Switching Noise in High-Speed Circuit” reported by the inventors in IEEE Transactions on Microwave Theory and Techniques (2006).

Please refer to FIG. 2, which shows the simulated and measured results for the substrate for circuits according to this invention. The horizontal axis and vertical axis are frequency and signal attenuation, respectively. As shown in FIG. 2, there are two stop bands approximately existing between 2.6-5.2 GHz and 5.8-7.1 GHz, respectively. In the stop band between 2.6-5.2 GHz, noises are reduced over 60 dB on average. In the stop band between 5.8-7.1 GHz, noises are reduced over 25 dB on average. Thus, it can be seen the EBG structure, according to this invention, provides broadband and excellent noise suppression.

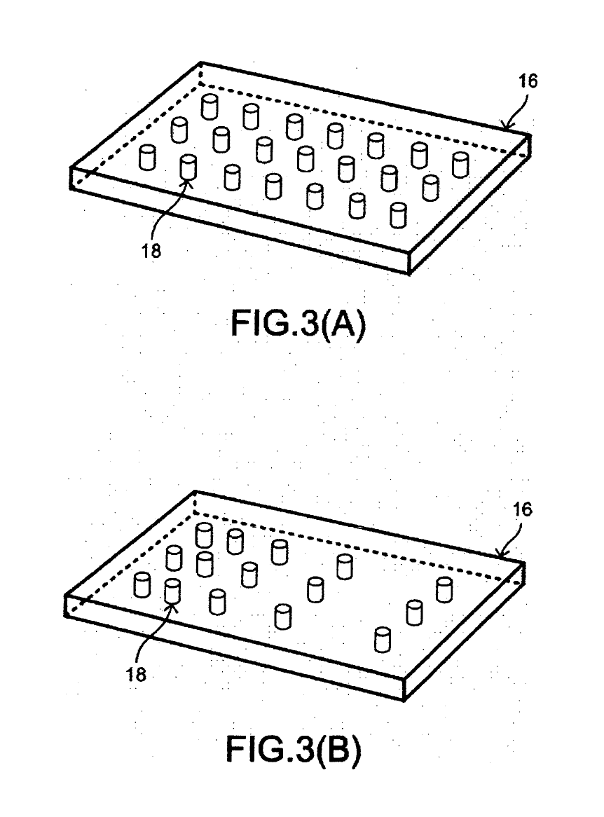

Please refer to FIG. 3. FIG. 3(A) and: FIG. 3(B) are perspective drawings of the first dielectric layer 16. In FIG. 3(A), the second dielectric materials 18 are periodically embedded in the first dielectric layer 16. In one embodiment according to this invention, the distance between two of the plurality of second dielectric materials 18 equals 12.5 mm. In FIG. 3(B), the distance between two of the plurality of second dielectric materials 18 is gradually increased. The two embodiments above can both provide the function of eliminating noises.

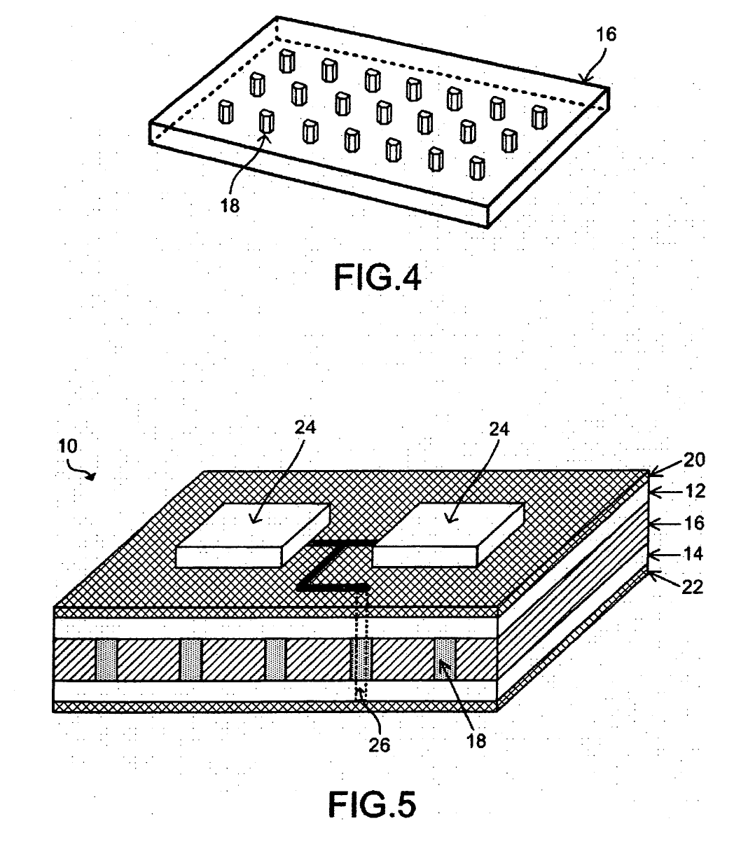

Besides, according to this invention, the shape of each of the plurality of second dielectric materials 18 can be a cylinder, as shown in FIG. 3(A) and FIG. 3(B), or an irregular pillar, as shown in FIG. 4. The shape of each of the plurality of second dielectric materials 18 can also be other crooked pillar instead of straight pillar.

In actual applications the substrate 10 can be a multi-layer printed circuit board. Therefore, as shown in FIG. 5, the substrate 10 can further include a first signal layer 20 above the first voltage reference plane 12 and a second signal layer 22 under the second voltage reference plane 14. The first signal layer 20 and the second signal layer 22 are usually used for mounting IC chips 24, chip resistors, and chip capacitors. The signal layers also provide connections between the chips 24 and/or other connectors. The first signal layer 20 and the second signal layer 22 are connected to each other with vias 26. According to this invention, one via 26 can be embedded in one of the second dielectric materials 18 or independent from the second dielectric materials 18, as shown in FIG. 5. Certainly, besides the first dielectric layer 16, there can be other dielectric layers or signal layers between the two power supply planes (i.e. the first voltage reference plane 12 and the second voltage reference plane 14).

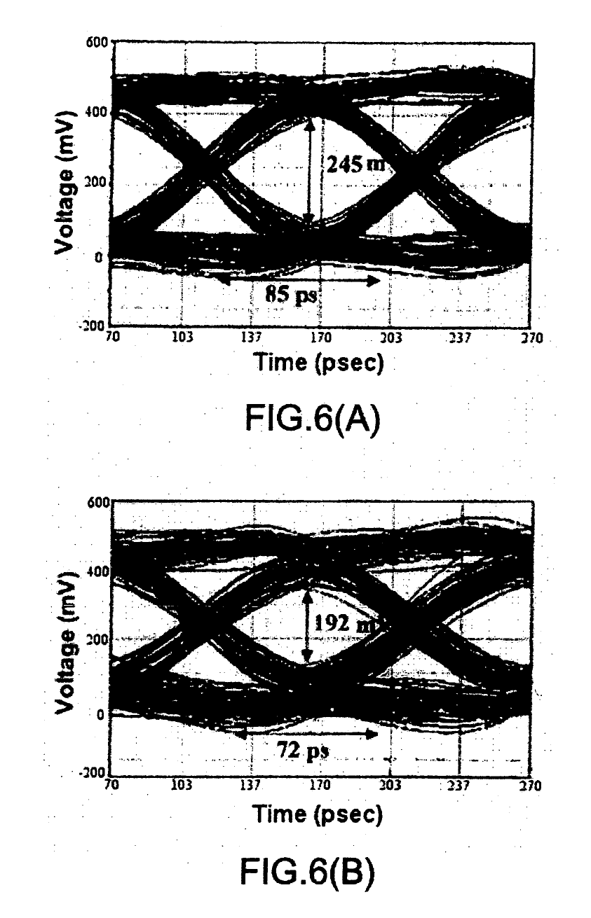

Please refer to FIG. 6. FIG. 6(A) shows the simulated eye diagram for the substrate according to this invention. FIG. 6(B) shows the simulated eye diagram for a substrate without the second dielectric materials 18. The maximum eye open (MEO) and maximum eye width (MEW) in FIG. 6(A) are 245 mV and 85 ps, respectively. In FIG. 6(B), the MEO and MEW are 192 mV and 72 ps, respectively. As it can be seen, compared with the substrate without the second dielectric materials 18, the substrate according to this invention substantially degrades noises and improves signal quality accordingly.

As mentioned above, the EBG structure, according to this invention, is located within the dielectric layer between two power supply planes. Thus, the metal layers of the power supply planes are not destroyed. Therefore, the substrate according to this invention provides good return paths for currents from signal layers and improves quality of signal transmission. Furthermore, the EBG structure, according to this invention, provides broadband noise suppression and accordingly prevents EMI problems in high-speed circuits.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A substrate for circuits, comprising:
a first voltage reference plane;
a second voltage reference plane;
a first dielectric layer between the first and second voltage reference planes; and
a plurality of second dielectric materials, each of the plurality of second dielectric materials being embedded in the first dielectric layer and comprising a first end contacted with the first voltage reference plane and a second end contacted with the second voltage reference plane,
wherein the dielectric constant of the first dielectric layer is different from the dielectric constant of the second dielectric materials.

2. The substrate of claim 1, wherein the dielectric constant of the second dielectric materials is higher than the dielectric constant of the first dielectric layer.

3. The substrate of claim 1, wherein each of the plurality of the second dielectric materials is ceramic material.

4. The substrate of claim 1, wherein the shape of each of the plurality of second dielectric materials is a cylinder.

5. The substrate of claim 1, wherein the shape of each of the plurality of second dielectric materials is an irregular pillar.

6. The substrate of claim 1, wherein the plurality of second dielectric materials are periodically embedded in the first dielectric layer.

7. The substrate of claim 1, wherein the distance between two of the plurality of second dielectric materials is gradually increased.

8. The substrate of claim 1, wherein the first voltage reference plane is parallel to the second voltage reference plane.

9. The substrate of claim 1, wherein the first voltage reference plane and the second voltage reference plane are metal planes.

10. The substrate of claim 1, the substrate further comprising:
a plurality of vias, at least a first via among the plurality of vias being embedded in one of the plurality of second dielectric materials.

11. The substrate of claim 10, wherein a first signal layer is above the first voltage reference plane, and at least one electric device is mounted on the first signal layer.

12. The substrate of claim 11, wherein the first via is electrically connected to the electric device.

13. The substrate of claim 1, wherein each of the first and second ends is respectively plated with a conductive metal to contact with the first or the second voltage reference planes.

14. The substrate of claim 13, wherein the conductive metal is silver.
